(19) United States
(12) Patent Application Publication
(10) Pub. No.: US 2013/0209672 A1
(43) Pub. Date: Aug. 15, 2013

(54) COMPONENT HAVING A THROUGH-CONNECTION

(71) Applicants: Jochen REINMUTH, Reutlingen (DE); Frank SCHNELL, Kornwestheim (DE); Heribert WEBER, Nuertingen (DE); Erhard HIRTH, Ellhofen (DE); Yvonne BERGMANN, Reutlingen (DE)

(72) Inventors: Jochen REINMUTH, Reutlingen (DE); Frank SCHNELL, Kornwestheim (DE); Heribert WEBER, Nuertingen (DE); Erhard HIRTH, Ellhofen (DE); Yvonne BERGMANN, Reutlingen (DE)

(21) Appl. No.: 13/763,223

(22) Filed: Feb. 8, 2013

(30) Foreign Application Priority Data
Feb. 10, 2012 (DE) 10 2012 201 976.6

(51) Int. Cl. H05K 3/00

(52) U.S. Cl. CPC H05K 3/0094
USPC 427/97.8

(57) ABSTRACT

A method for manufacturing a component having a through-connection. The method includes providing a semiconductor substrate, forming a recess in the semiconductor substrate, and introducing into the recess a pourable starting material which has a metal. The method furthermore includes carrying out a heating process, an electrically conductive structure forming the through-connection being developed from the pourable starting material.

### CROSS REFERENCE

The present application claims the benefit under 35 U.S.C. §119 of German Patent Application No. DE 102012201976.6 filed on Feb. 10, 2012, which is expressly incorporated herein by reference in its entirety.

### FIELD

The present invention relates to a method for manufacturing a component having a through-connection.

BACKGROUND INFORMATION

Electrically conductive structures which extend through a substrate are becoming more and more important. Such structures which are also referred to as through-connections or vias (vertical interconnect access) make it possible to manufacture space-saving components. This advantage is, for example, used for the development of ever smaller components (MEMS, micro-electro-mechanical systems). One concept applied in this regard and referred to as “MEMS 3D integration” is related to stacking individual components or chips (in particular a sensor, a sensor cap, and an evaluation circuit) to form a so-called package, vertical electrical connections being implemented with the aid of through-connections. It is usually strived for that the through-connections are designed to have a relatively high mechanical stability and a relatively low electrical resistance.

Such properties apply to metallic through-connections which may be manufactured by metal coating recesses or holes of a substrate. For the metallic filling, processes such as a chemical vapor deposition (CVD) or an electroplating process are typically carried out. These conventional metal coating processes are, however, associated with a relatively high complexity and relatively high costs and require the use of expensive processing equipment. Moreover, other layers (e.g., a diffusion barrier layer and a starting layer or seed layer in the case of an electroplating process) are implemented in addition to the actual metal coating process.

### SUMMARY

An object of the present invention is to provide an improved approach to the manufacture of a component having a metallic through-connection.

According to an example embodiment of the present invention, a method is provided for manufacturing a component having a through-connection. The example method includes providing a semiconductor substrate, forming a recess in the semiconductor substrate, and introducing into the recess a pourable starting material which has a metal. The method furthermore includes carrying out a heating process, an electrically conductive structure forming the through-connection being developed from the pourable starting material.

The example method enables a simple and cost-effective manufacture of the through-connection which extends (at least partially) through the semiconductor substrate. This is, in particular, due to the use of the pourable metallic starting or filling material which may be introduced into the recess in a relatively easy manner, solidified through heating, and thereby “converted” into the electrically conductive structure. Compared to conventional metal coating processes, such as CVD or electroplating processes, the metal coating may be carried out in this way with less complexity and using more cost-effective processing equipment. The formation of additional diffusion barrier layers and starting layers may be dispensed with, thus allowing for a space-saving geometry of the through-connection. Moreover, the metal plating may be carried out locally in contrast to CVD or electroplating processes.

In one preferred specific embodiment, the semiconductor substrate is a silicon substrate. In particular in such an embodiment, the component to be manufactured may, for example, be a micromechanical component or a sensor chip, e.g., an inertial sensor. Alternatively, the component may be an integrated circuit (IC), for example, or a semiconductor chip. In this case, it is also possible that the provided semiconductor substrate is formed before the through-connection is formed and already has the appropriate micromechanical and/or electrical or electronic structures.

In another preferred specific embodiment, the pourable starting material has metallic particles. In this way, it is possible to reliably transfer the pourable starting material into the electrically conductive through-connection structure by heating. Within the scope of the heating process, the metallic particles may be connected to one another or sintered to form a solidified structure. For this purpose, metallic particles having a size in the nanometer range (“nanoparticles”) are preferably used. As the material for the particles, a metal such as silver, but also another metal such as copper, may be considered.

In another preferred specific embodiment, the pourable starting material is an ink. In this way, it is possible to carry out the heating process for forming the electrically conductive structure at a relatively low temperature. The ink may be in the form of a liquid in which the metal may be present in particular in the form of the previously described particles or nanoparticles (“nanoparticle ink”). As the liquid integral part, the ink may include one or multiple organic solvent(s). In this case, the heating process leads to an evaporation of the liquid portion in addition to the above-named sintering of the metal particles, thus resulting in a drying of the ink.

In one alternative preferred specific embodiment, the pourable starting material is a paste. The paste may have a viscous integral part in which the metal may (also) be present in particular in the form of the above-described particles or nanoparticles. The viscous integral part may include one or multiple organic solvent(s) as well as one or multiple other components (e.g., plastics or polymers). In this case, the heating process may cause a curing of the paste or the viscous integral part of the paste, associated with the solvent(s) being expelled, in addition to the above-described sintering of the metal particles.

With the aid of the example method, it is possible for not just a single through-connection, but for multiple or a plurality of through-connections to be formed generally simultaneously or in parallel in the semiconductor substrate. For this purpose, multiple recesses are accordingly formed in the substrate into which the pourable starting material is introduced and which are converted into through-connections by heating.

In the course of the introduction of the pourable starting material into the recess, it is also possible to provide a part of an outside of the semiconductor substrate with the pourable starting material. In this way, it is possible to simultaneously manufacture the through-connection, produced by heating, and a connecting structure present at the substrate side. In this case, it may also be provided that the connecting structure is formed as a rewiring or a printed conductor structure which may be implemented by applying the pourable starting material to the semiconductor substrate having an appropriate structure.

The pourable starting material may be applied to the semiconductor substrate and thus introduced into the recess in various ways. For example, it may be considered that the pourable starting material is applied to or dispensed on the semiconductor substrate using an appropriate metering device which may be positioned in the area of the recess.

In another preferred specific embodiment, it is provided that the pourable starting material is introduced into the recess (or applied to the semiconductor substrate) with the aid of a printing process. In this way, it is possible to provide the recess locally (or also multiple recesses as well as an outside of the substrate) with the pourable starting material in a cost-effective and targeted manner, thereby metal-coating it. Printing processes, which may be considered, are, for example, an inkjet printing process or a screen printing process.

In another preferred specific embodiment, an insulating layer is formed in the recess. Due to the insulating layer, the electrically conductive structure which is (subsequently) produced from the pourable starting material may be insulated from the surrounding semiconductor substrate or substrate material. The insulating layer may not only be formed within the recess, but also outside the recess or at an outside of the semiconductor substrate in order to be able to also insulate a connecting structure of the through-connection situated here.

In the example method, the wetting behavior of the pourable starting material is used to be able to wet and thereby to metal-coat certain areas in a targeted manner using the starting material. To reliably delimit the areas to be wetted, it is provided in another preferred specific embodiment for a non-adhesive layer to be formed on the semiconductor substrate before the pourable starting material is introduced into the recess. Due to the non-adhesive layer, which may be designed to have an appropriate structure, the areas to be wetted (i.e., the recess, but also the areas on an outside of the substrate for a connecting structure, for example) may be predefined. In this way, it is possible for a quantity of the pourable starting material suitable for the metal coating to be situated in these areas.

In another preferred specific embodiment, the recess into which the pourable starting material is introduced is formed as a through hole in the semiconductor substrate. It is thus possible to introduce the pourable starting material into the recess by using vacuum, e.g., by using a vacuum table. In this way, it is possible to reliably fill or wet the recess using the pourable starting material.

In one alternative preferred specific embodiment, the recess into which the pourable starting material is introduced is formed as a blind hole in the semiconductor substrate. Such a recess is accessible only from one substrate side. Furthermore, after carrying out the heating process, a thinning of the semiconductor substrate on an (opposing) substrate side is carried out to expose here the electrically conductive structure which was produced by heating from the pourable starting material.

In another preferred specific embodiment, the method also includes forming a contact structure which is connected to the electrically conductive structure. The contact structure which may, for example, be produced on the semiconductor substrate after the manufacture of the through-connection may be formed by carrying out comparable steps, i.e., applying a pourable metallic starting material (e.g., metallic particles added to an ink or a paste) and heating. For applying the pourable starting material, here too, a cost-effective printing process may be used. The contact structure may be provided on a substrate side which is opposed to the substrate side on which a connecting structure is situated which has been produced, if needed, at the same time as the through-connection. For the contact structure, an embodiment in the form of a rewiring or printed conductor structure may (also) be considered.

The contact structure may also be a buried structure, in particular a buried printed conductor structure, which may be formed within the scope of providing the semiconductor substrate and thus prior to manufacturing the through-connection. The buried contact structure may be embedded into an insulation or an insulating layer. Furthermore, the buried contact structure may be situated in the area of a first substrate side, and the through-connection may extend from an opposing second substrate side to the contact structure. Within the scope of the through-connection manufacture, it may be provided that the recess (starting from the second substrate side) is designed to reach the insulation of the buried contact structure, one part of the insulation being exposed. Furthermore, an (additional) insulating layer may be formed in the recess. Before introducing the pourable starting material into the recess, the insulating layer and the insulation of the buried contact structure may be opened in a bottom area of the recess. In this way, the buried contact structure may be exposed or opened in this area, thus allowing the pourable starting material to be (also) applied to the contact structure.

The advantageous embodiments and refinements of the present invention described above—except for the cases of unambiguous contingencies or incompatible alternatives, for example—may be used alone or also in any combination with each other.

The present invention is explained below in greater detail with reference to the figures.

### BRIEF DESCRIPTION OF THE DRAWINGS

FIGS. 1 through 7 show a method for manufacturing a component having a through-connection, each in a schematic lateral sectional illustration.

FIG. 8 shows an associated flow chart of a method for manufacturing a component having a through-connection.

FIGS. 9 through 12 show another method for manufacturing a component having a through-connection, each in a schematic lateral sectional illustration.

FIG. 13 shows a schematic lateral sectional illustration of a micromechanical component having a through-connection.

FIGS. 14 through 17 show another method for manufacturing a component having a through-connection, each in a schematic lateral sectional illustration.

### DETAILED DESCRIPTION OF EXAMPLE EMBODIMENTS

Based on the following figures, specific embodiments of a simple and cost-effective method for manufacturing a component having a metallic through-connection 155 are described. Through-connection 155 produced according to the example method distinguishes itself by a space-saving geometry, a high mechanical stability, and a low electrical volume resistance. During the manufacturing process, processes, e.g., CMOS (complementary metal oxide semiconductor) processes and MEMS processes, which are customary in the semiconductor or microsystem technology, may be carried out, and customary materials may be used, so this will be discussed only partially. It is also pointed out that in addition to the illustrated and described method steps and processes, other method steps may be carried out to complete the manufacture of the shown components.

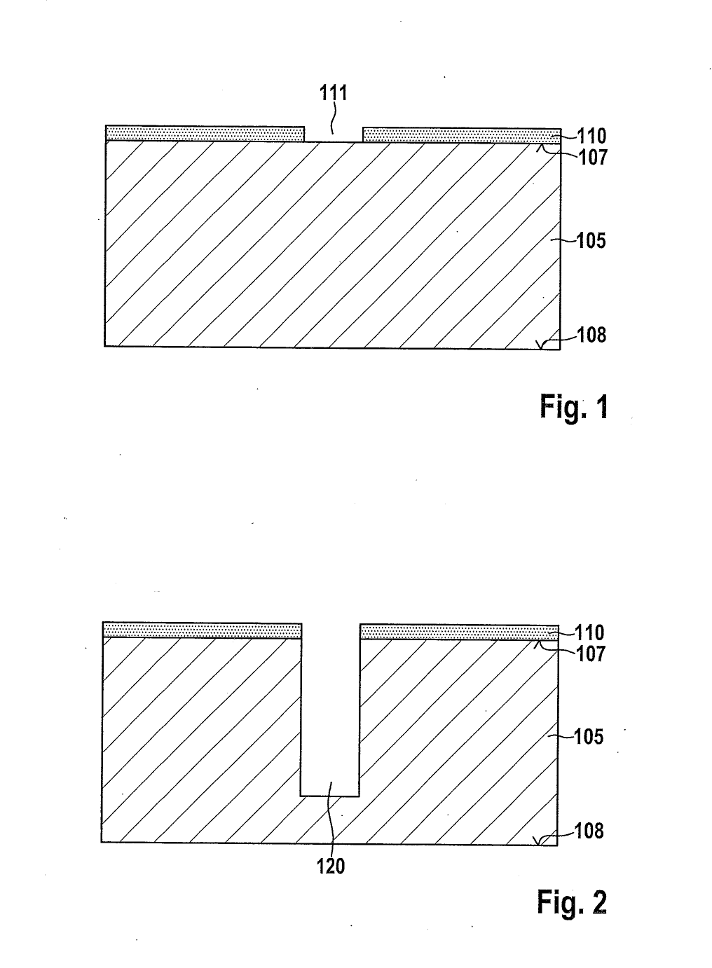

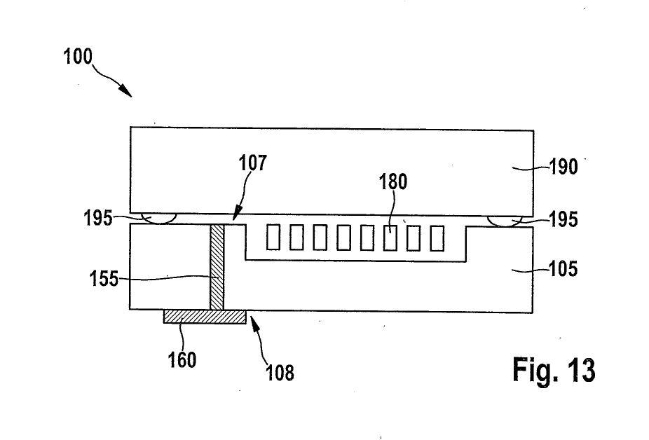

FIGS. 1 through 7 show a method for manufacturing a component 100 having a metallic through-connection 155, each in a schematic lateral sectional illustration. The method steps carried out in the method are also combined in the flow chart of FIG. 8 which is also used as reference in the following. Component 100 manufactured here may, for example, represent an integrated circuit or a semiconductor chip. Possible examples thereof include an application-specific integrated circuit (ASIC), a memory component, and a processor or a microprocessor. Furthermore, component 100 may also be a micromechanical component or a sensor chip. Such a possible embodiment will be explained below in greater detail in the context of FIG. 13.

In the method, a semiconductor substrate 105 is provided in a step 201 (cf. FIG. 8) which is shown only sectionally in FIGS. 1 through 7. Substrate 105 may, in particular, be a wafer made of silicon. It is possible that provided substrate 105 already has micromechanical and/or electrical or electronic structures (not illustrated). In this regard, the subsequently described steps for manufacturing through-connection 155 may represent a so-called “via-last process” which is carried out at the end of the manufacture of component 100. It is, however, also possible that the manufacture of through-connection 155 represents a so-called “via-first process” which is carried out at the start of the manufacture of component 100.

In a subsequent step 202 (cf. FIG. 8), which is described with reference to FIGS. 1 through 4, a recess 121 (“through-contact hole”) which is provided with an insulation 130 is formed in substrate 105 for through-connection 155 which is produced later. For this purpose, a structured mask layer 110 is initially formed, as shown in FIG. 1, on one side 107 of substrate 105 which is also referred to in the following as front side 107. Mask layer 110 has an opening 111 which predefines a trench etching area. Mask layer 110 may, for example, be an oxide layer (silicon oxide) or also a metal layer. To form mask layer 110, a deposition process and a subsequent photolithographic structuring and etching process may be carried out.

After mask layer 110 is formed, a trench etching process is carried out, whereby a recess 120 is formed in substrate 105 in the form of a blind hole as shown in FIG. 2. In the course of the etching process, substrate material (silicon) is removed in the etching area predefined by opening 111 of mask layer 110 up to an appropriate depth starting from front side 107 of substrate 105. In the top view, recess 120 may have a circular, or any other, for example, a rectangular geometry, which depends on the design of opening 111 of mask layer 110. The etching process is an anisotropic etching process, in particular a deep reactive ion etching (DRIE) process.

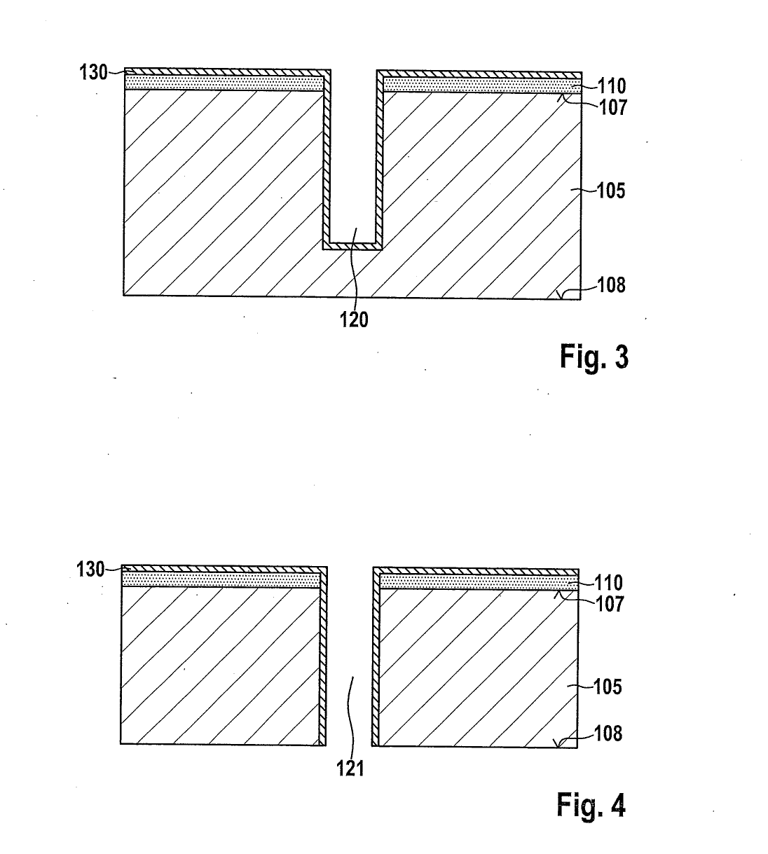

In the context of step 202, a continuous insulating layer 130 is also formed, as shown in FIG. 3, to insulate through-connection 155, which is produced later, from surrounding substrate 105 or the substrate material. Insulating layer 130 is situated on mask layer 110 in recess 120, i.e., in a bottom area and one or multiple side wall areas of recess 120, and also on the outside of substrate 105 or outside of recess 120. Insulating layer 130 may, for example, have an oxide material (silicon oxide), or also a polymer material, and it may be applied to substrate 105 (and its mask layer 110) with the aid of an appropriate deposition process. In order to largely suppress the occurrence of a parasitic capacitance between through-connection 155 and substrate 105, insulating layer 130 is preferably designed to have the greatest possible layer thickness.

Subsequently, a thinning of substrate 105 takes place, as shown in FIG. 4, on a substrate side 108 opposing front side 107, the former also being referred to in the following as back side 108. In this way, blind hole 120, which was previously only accessible in the area of front side 107, is also exposed on back side 108 so that now a recess 121 or a through hole 121 is present which penetrates entire substrate 105. When substrate material is removed from back side 108 of substrate 105, which may take place with the aid of a grinding or polishing process, e.g., CMP (chemical mechanical polishing), a part of insulating layer 130 is also removed (i.e., in particular a part which was originally a bottom section).

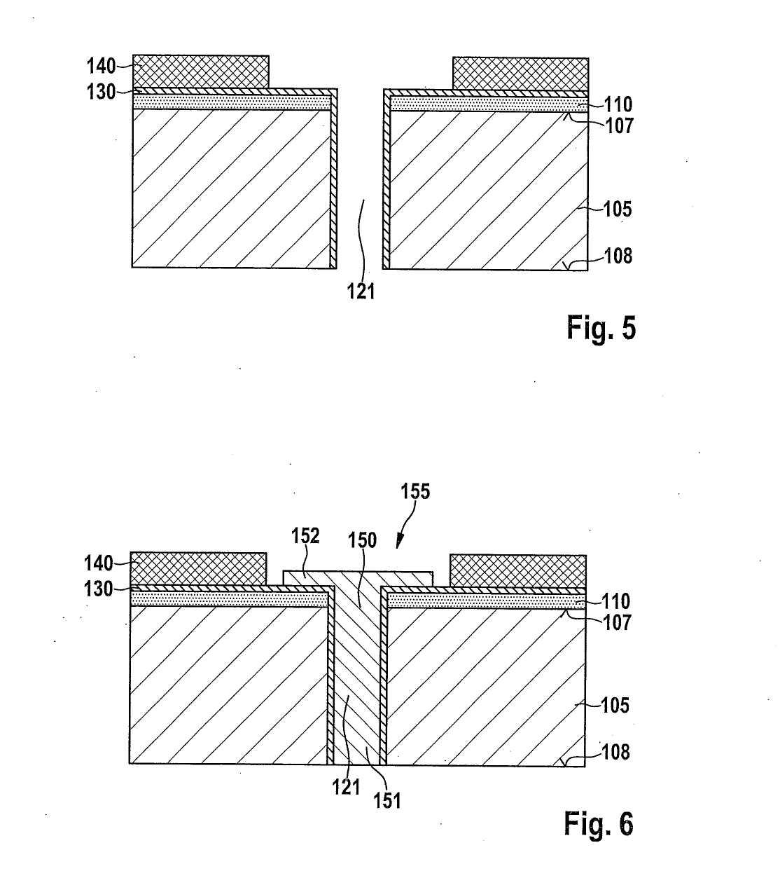

Following the formation of “insulated” recess 121, a non-adhesive layer 140 is formed outside of recess 121 on substrate 105 or on its insulating layer 130 in a subsequent step 203 (cf. FIG. 8) which is illustrated in FIG. 5. Non-adhesive layer 140 is used to establish wetting areas for a subsequently applied conductive starting material 150 and the sections to be metal-coated thereby on (and in) substrate 105. Non-adhesive layer 140, which is used for wetting protection, may, for example, include a wax material, e.g., a paraffin oil, and be produced by being imprinted. Alternatively, coating using a structurable foil lacquer may also be provided to form non-adhesive layer 140, for example. As indicated in FIG. 5, non-adhesive layer 140 may be designed to have a structure which surrounds recess 121 and an area outside of recess 121 (e.g., in an annular manner).

In another step 204 (cf. FIG. 8), which is shown in FIG. 6, a pourable and metal-containing starting material 150 is subsequently applied to substrate 105 and thus introduced into recess 121. For this purpose, a wetting of substrate 105 or of its insulating layer 130 with starting material 150 may take place both in a section 151 within previously produced recess 121 and in a front-side section 152 outside of recess 121, which may be established with the aid of non-adhesive layer 140.

Pourable starting material 150, which will be explained in the following in greater detail, has such a viscosity and such filling and wetting properties that it is possible to (generally) entirely wet the side walls of recess 121 and to fill recess 121 without cavities or voids. It may thus be ensured that boundary conditions with regard to the electrical resistance and the mechanical stability of later through-connection 155 may be met, but also with regard to the ability to further process substrate 105.

As pourable starting material 150, a conductive ink may, for example, be used which may include the metal provided for metal-coating in the form of metal particles, in particular having a size in the nanometer range. The particles or nanoparticles may, for example, be formed from silver or also another metal, e.g., copper (“nano-silver ink,” “nano-copper ink”). As the liquid integral part or carrier, the ink may include one or multiple organic solvent(s). These are preferably easily expellable solvents.

Alternatively, pourable starting material 150 may also be provided in the form of a conductive paste in which the metal used for metal coating may also be included in the form of metal particles, in particular having a size in the nanometer range. As the metal, silver, or any other metal, e.g., copper, may again be considered (“nano-silver paste,” “nano-copper paste”). In addition to metallic particles, the paste has a viscous integral part which may include one or multiple (in particular easily expellable) organic solvents as well as one or multiple other components (e.g., plastics or polymers).

Pourable metallic starting material 150 may be applied in various ways. For example, a suitable metering device may be positioned in the area of recess 121 to dispense starting material 150 in this area. Furthermore, a printing process may also be carried out, whereby it is possible to apply starting material 150 locally onto substrate 105 (or its insulating layer 130) in a cost-effective and targeted manner and to thereby fill recess 121. When using ink as starting material 150, an inkjet process may be carried out, in particular. When using paste as starting material 150, a screen printing process may be carried out, however.

The design of through hole 121 furthermore offers the option of assisting the reliable filling of through hole 121 with starting material 150 applied in the area of substrate front side 107 by providing a vacuum in the area of back side 108, thus resulting in starting material 150 being sucked through or into through hole 121. For this purpose, substrate 105 may, for example, be situated on a vacuum table.

In another step 205 (cf. FIG. 8), a temperature or heating process is carried out, whereby pourable starting material 150 solidifies and an electrically conductive or metallic structure 155, which is used as a through-connection, is formed. Here, substrate 105 is heated to a temperature suitable for the solidification. When using a silicon substrate 105, through-connection 155 produced in this way may be referred to as “through silicon via” (TSV). Through-connection 155 has section 151 extending through recess 121 and section 152 which is present on the front side or outside of recess 121 and which may be used as the connecting structure of through-connection 155.

In one embodiment of pourable starting material 150 as an ink, the heating process results, in addition to the sintering of the metal particles, in the liquid portion being vaporized or the solvent(s) being expelled, and thus in a drying of the ink. The use of ink makes it possible to carry out the heating process at a relatively low temperature, e.g., in a temperature range between 100° C. and 400° C. In this way, it is possible to achieve a high compatibility of the method applied (if necessary) as the “via-last process” with CMOS and/or MEMS manufacturing steps carried out previously. A low heating temperature may, in particular, be present when easily expellable solvents are used. The heating of the ink may be associated with such a volume reduction that section 151 of metal-coated through-connection 155 no longer fills recess 121 completely, but is present in the form of a side wall coating of recess 121. The side wall coating may enclose a cavity and transition into section 152 at the front-side rim of recess 121 (not illustrated).

With regard to the use of a paste as pourable starting material 150, the heating process is carried out at a higher temperature, e.g., up to 800° C. Due to the heating, a curing of the paste or the viscous paste portion, associated with the solvent(s) being expelled, is caused in addition to the sintering of the metal particles. Since a paste, in contrast to an ink, may be subject to volume expansion during heating, the used paste preferably has a thermal expansion coefficient which is adapted to the substrate material (silicon) so that mechanical stress may be prevented from occurring. In through-connection 155 produced by curing of the paste, section 151 may (continue to) fill out recess 121 completely.

Instead of applying pourable starting material 150 (step 204) and heating starting material 150 to “convert” it into through-connection 155 (step 205) consecutively, these steps 204, 205 may also be carried out (generally) simultaneously. Such a procedure may, in particular, be considered for the above-described use of vacuum when applying starting material 150 to bring about a drying or curing of starting material 150 while it is sucked through recess 121.

With regard to outside section 152 of through-connection 155, which may be used as a connecting structure, it may be considered that this section 152 is present in the form of a rewiring or printed conductor structure or that it transitions into such a structure. This may be implemented by applying pourable starting material 150 onto substrate 105 (or its insulating layer 130) having a corresponding shape. Non-adhesive layer 140 is (previously) formed accordingly having a structure corresponding thereto.

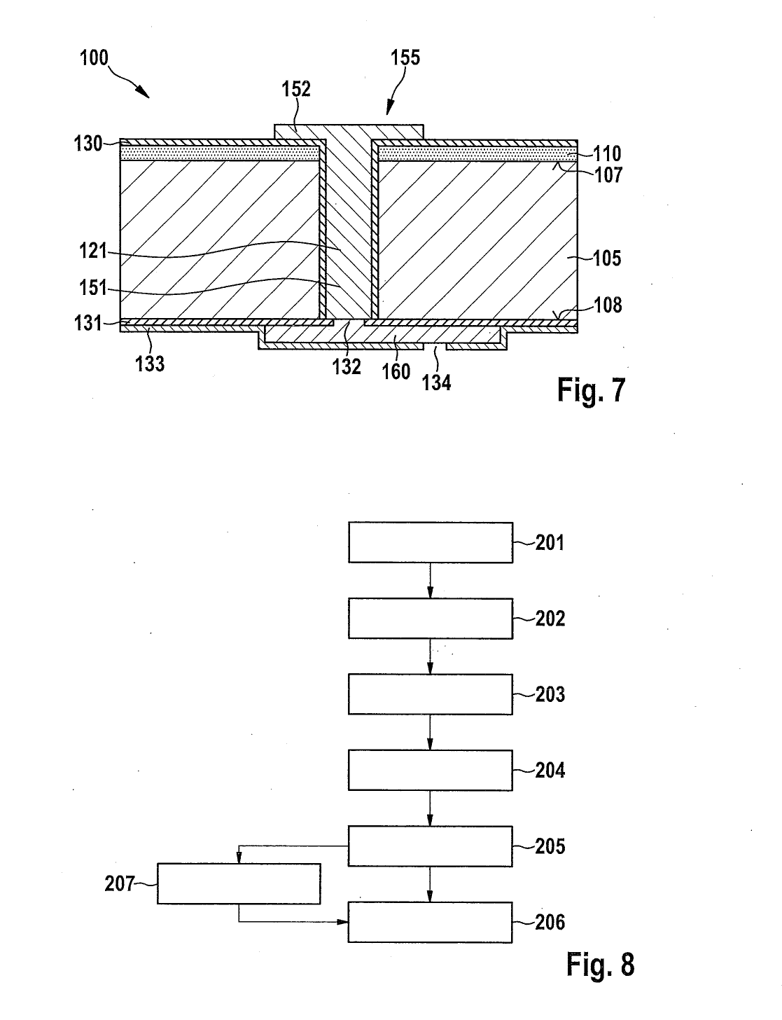

In another step 206 (cf. FIG. 8), other processes are carried out to complete component 100 shown in FIG. 7. These processes include, for example, removal of non-adhesive layer 140; wax or lacquer stripping or a polishing process such as CMP may be carried out for this purpose. A portion of starting material 150, which has possibly been applied on non-adhesive layer 140 during the application of the starting material and may be metal-coated due to the heating process, may be removed in the process.

Moreover, another connecting structure, which is referred to in the following as contact structure 160 and which is in contact with through-connection 155, is formed in the area of back side 108 of substrate 105. Contact structure 160 may be designed in the form of a rewiring or printed conductor structure as (other) connecting structure 152. To form contact structure 160, another insulating layer 131 (for example, silicon oxide) is initially applied on substrate back side 108, and an opening 132 is formed in insulating layer 131 in the area of through-connection 155. The subsequent production of contact structure 160, which is formed on insulating layer 131 and on through-connection 155 open in the area of substrate back side 108, may take place comparably to through-connection 155, i.e., by applying a pourable metallic starting material (e.g., metallic particles added to an ink or a paste) and heating. For applying the pourable starting material, here too, a cost-effective printing process may be used. The use of a non-adhesive layer for establishing the wetting areas may also be provided.

In the context of step 206, other processes may furthermore be carried out, such as a passivation of the front and/or back side of substrate 105. This may, for example, take place by applying a suitable oxide or nitride material. In FIG. 7, such a passivation is indicated based on passivating layer 133 formed on insulating layer 131 and on contact structure 160 in the area of substrate back side 108. Passivating layer 133 may also have an opening 134 (“contact hole”) in the area of contact structure 160 to enable a contacting of contact structure 160, e.g., via a bonding wire or a solder or a solder bump. A comparable embodiment may also be provided in the area of substrate front side 107, i.e., that (another) passivating layer may be formed on insulating layer 130 and on connecting structure 152, having an opening in the area of connecting structure 152 (not illustrated) if necessary.

It is possible to produce multiple components 100 in parallel from or on substrate 105. Another process which may be carried out in the context of step 206 is therefore a separation process to separate component 100 from other components 100. In this regard, it is pointed out that with the aid of the method, a plurality of through-connections 155 may be formed essentially simultaneously or in parallel in substrate 105 by carrying out the above-described method steps, i.e., multiple insulated recesses 121 may be produced accordingly in substrate 105 and multiple through-connections 155 may be manufactured by applying starting material 150 (in particular with the aid of a printing process) and by heating same.

The method may be modified in such a way that recess 120 is not manufactured with the aid of the above-described trench etching process. Instead, a laser may be used to accordingly remove substrate material up to a certain depth starting from substrate front side 107. In such a process, which is referred to as “laser drilling,” the use of mask layer 110 may be dispensed with. The consequence thereof is that subsequently formed insulating layer 130 is also situated outside of recesses 120 and 121 directly on actual substrate 105 or on its front side 107 (not illustrated).

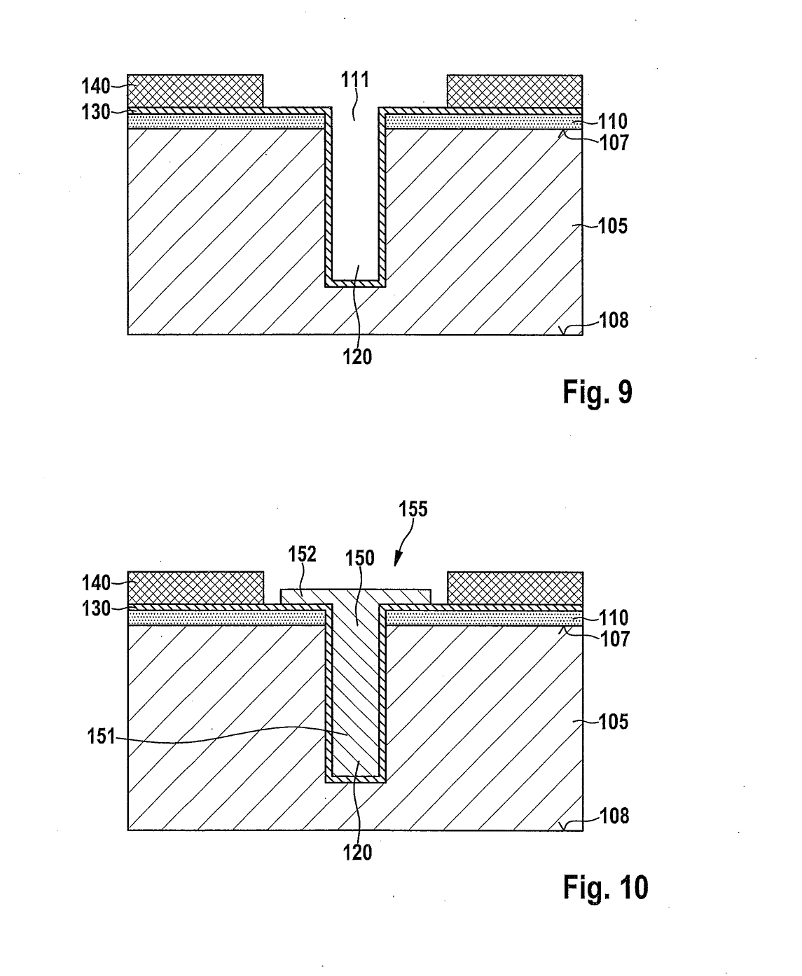

In another variant, a blind hole 120, which may be subsequently “ground open,” is (initially) metal-coated instead of metal-coating a through hole 121. A method carried out in this regard for manufacturing a component 100 having a through-connection 155 is described in the following with reference to FIGS. 9 through 12. It is pointed out here that reference should be made to the preceding statements with regard to already described details which relate to identical or coinciding components and structures, usable materials and method steps, possible advantages, etc. Furthermore, the flow chart of FIG. 8 is also used as reference here.

In the method, a semiconductor substrate 105, in particular a wafer made of silicon, is provided again in a step 201 (cf. FIG. 8). It is possible that provided substrate 105 already has micromechanical and/or electrical or electronic structures (not illustrated).

In a subsequent step 202 (cf. FIG. 8), a recess 120 coated with an insulation 130 is formed in substrate 105, this recess being present in the form of a blind hole open in the area of substrate front side 107, as shown in FIG. 9. Here, the above-described processes may be carried out again, i.e., forming a mask layer 110 on front side 107 having an opening 111; carrying out a trench etching process for producing recess 120; and forming an insulating layer 130 in recess 120 and outside of same or on mask layer 110.

After the formation of “insulated” recess 120, a non-adhesive layer 140, which is used as the wetting protection, is formed outside of recess 120 on substrate 105 or on its insulating layer 130 in another step 203 (cf. FIG. 8) which is also illustrated in FIG. 9. Non-adhesive layer 140 may be designed to have a structure which surrounds recess 120 and an area outside of recess 120.

In another step 204 (cf. FIG. 8), which is shown in FIG. 10, a pourable and a metal-containing starting material 150 is subsequently applied to substrate 105 and thus introduced into recess 120. A wetting of substrate 105 or its insulating layer 130 may be repeated in a section 151 within recess 120 and in a front-side section 152 outside of recess 120. Pourable starting material 150, which may be applied by “dispensation” or with the aid of a printing process, may, in particular, be an ink or a paste including metal particles or nanoparticles.

In a subsequent step 205 (cf. FIG. 8), a heating process is carried out, whereby pourable starting material 150 is converted into a solidified metallic through-connection 155. Here, the above-described drying or curing of starting material 150 and sintering of its metal particles may take place. Since through-connection 155 is produced in recess 120 formed as a blind hole in the present case, through-connection 155 or a section 151 of through-connection 155 does not (yet) extend through entire substrate 105. An outside section 152 of through-connection 155, which may be used as a connecting structure, may again be present in the form of a rewiring or printed conductor structure.

In another step 207 (cf. FIG. 8), through-connection 155 or its section 151 is exposed in the area of substrate back side 108, as shown in FIG. 11. For this purpose, a thinning of substrate 105 is carried out on back side 108, e.g., with the aid of a grinding or polishing process, such as CMP. When substrate material is removed from back side 108, a part of insulating layer 130 (i.e., in particular a part which was originally a bottom section) as well as, if necessary, a part of through-connection 155 is also removed. As furthermore illustrated in FIG. 11, non-adhesive layer 140 is also removed from substrate 105. This may be carried out prior to or after the thinning of substrate 105.

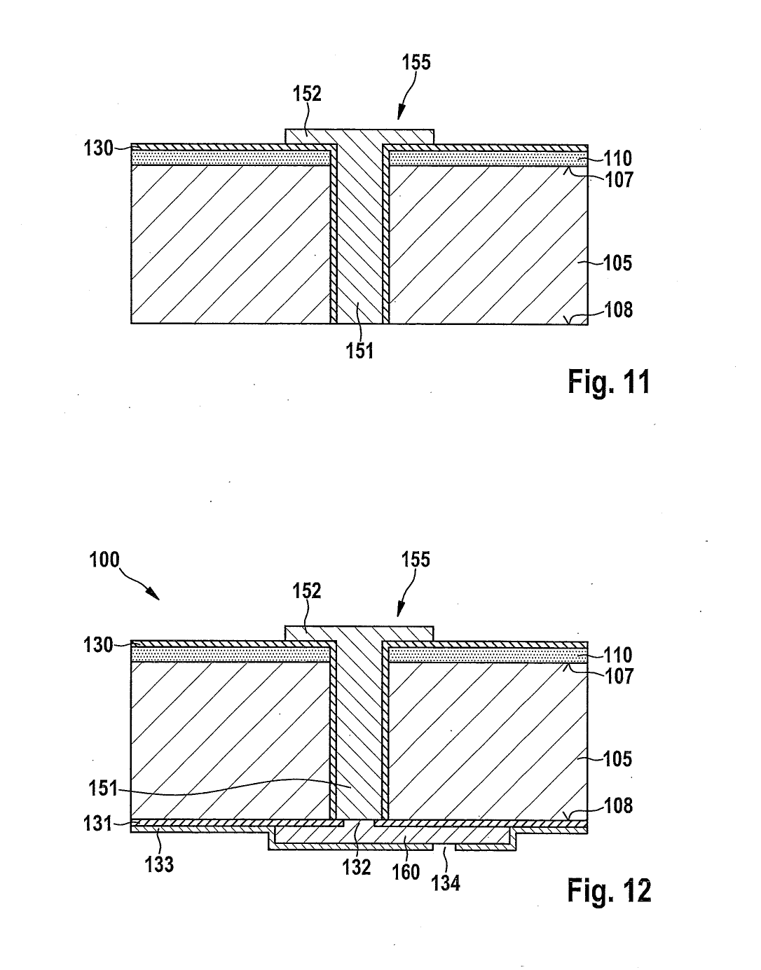

In another step 206 (cf. FIG. 8), combined processes may also be carried out to complete component 100 shown in FIG. 12. These processes include, in particular, forming another oxide layer 131 and a contact structure 160 connected to through-connection 155 in the area of substrate back side 108. Contact structure 160 may be designed in the form of a rewiring or printed conductor structure. In the context of step 206, other processes may also be carried out, such as a passivation of the front and/or back side of substrate 105, which is indicated in FIG. 12 based on (open) passivating layer 133 on insulating layer 131 and contact structure 160, as well as a separation process.

With the aid of the method described with reference to FIGS. 9 through 12, a plurality of through-connections 155 may also be formed generally simultaneously or in parallel in substrate 105 in that multiple insulated recesses 120 are produced in substrate 105, a starting material 150 is applied, a heating process is carried out, and substrate 105 is back-thinned. The method may also be modified in such a way that recess 120 is not manufactured with the aid of the above-described trench etching process, but instead by using a laser, and without using mask layer 110. The consequence thereof is that subsequently formed insulating layer 130 is also situated outside of recess 120 directly on substrate front side 107 (not illustrated).

The manufacture of through-connection 155 according to the above-described approaches may be used, in particular, within the scope of the manufacture of a micromechanical component. A possible specific embodiment of such a component 100 is schematically shown in FIG. 13 for illustration purposes. Component 100 has a substrate 105 having a metallic through-connection 155 and a contact structure 160 situated in the area of back side 108. Insulating, passivating, and mask layers are not illustrated in this case. In the area of front side 107, substrate 105 additionally has a micromechanical structure 180, having movable functional elements, which is also referred to as an SMM (surface micromechanical) structure. Micromechanical structure 180 may, for example, be designed to detect an acceleration. Micromechanical structure 180 and contact structure 160 may be electrically connected via through-connection 155 (as well as via a not-illustrated connecting or printed conductor structure of same in the area of front side 107).

In component 100 of FIG. 13, it may be provided that through-connection 155 is manufactured on or in substrate 105 only after micromechanical structure 180 is manufactured, thus representing a “via-last process.” Alternatively, through-connection 155 may also be manufactured first (“via-first process”) or the manufacture of micromechanical structure 180 and through-connection 155 may “overlap” in that process steps are, in particular, carried out together. For example, trench etching may be used for both forming a recess 120 for through-connection 155 and establishing a shape of micromechanical structure 180.

Substrate 105 of component 100 of FIG. 13, which is also referred to as a sensor or a functional substrate, is furthermore connected to another substrate 190 via a connecting layer 195. The other substrate 190, which includes silicon, for example, represents a cap substrate, with the aid of which micromechanical structure 180 may be hermetically sealed.

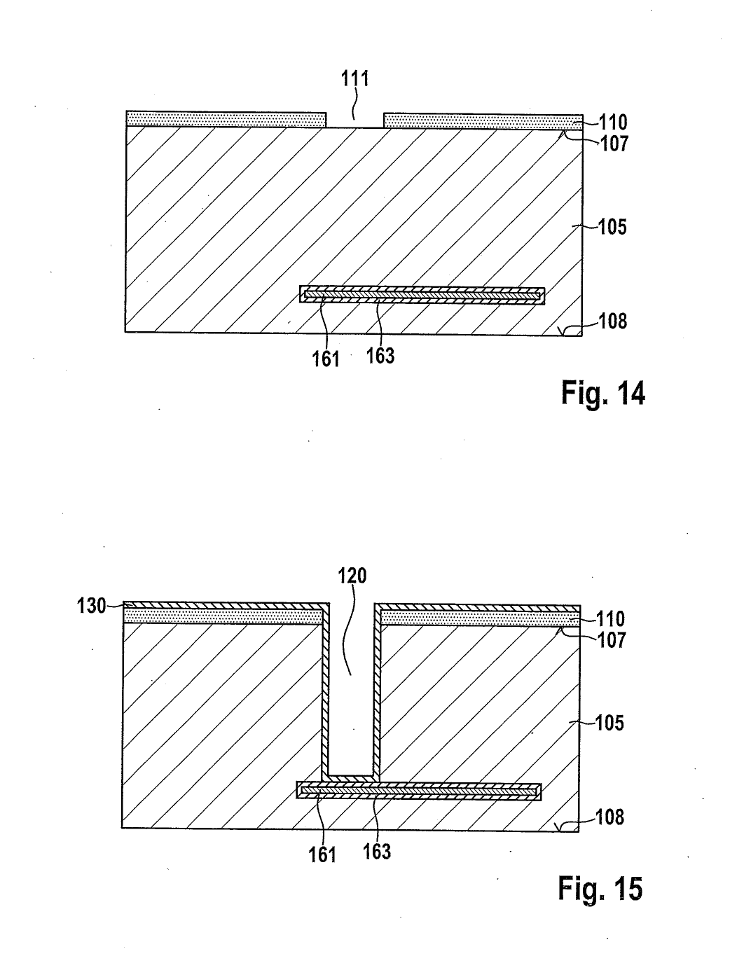

Another possible modification of the metal coating processes described with reference to FIGS. 1 through 7 and 9 through 12 is the manufacture of a through-connection 155 which is connected to a buried conductive structure. A method carried out in this regard for manufacturing a component 100 having a through-connection 155 is described in the following with reference to FIGS. 14 through 17. It is pointed out here that reference should be made to the preceding statements with regard to already described details which relate to identical or coinciding components and structures, usable materials and method steps, possible advantages, etc. Furthermore, the flow chart of FIG. 8 is also used as reference here.

In the method, a substrate 105 is provided in a step 201 (cf. FIG. 8). Provided substrate 105 is designed to have a buried conductive contact structure 161 situated in the area of substrate side 108, as shown in FIG. 14. Contact structure 161, which may be a buried printed conductor, in particular, is embedded in an insulation or an insulating layer 163. Contact structure 161 may, for example, include doped polysilicon, and insulating layer 163 may, for example, contain silicon oxide. Here, provided substrate 105 may be a wafer made of silicon or may originate from such a wafer, the wafer being provided with buried insulated contact structure 161 as well as, if necessary, additional layers and/or structures (not illustrated), by carrying out appropriate process steps. Therefore, the steps described in the following for manufacturing through-connection 155 may represent a “via-last process.”

In a subsequent step 202 (cf. FIG. 8), a recess 120 coated by an insulation 130 is formed in substrate 105. For this purpose, it may be provided that a mask layer 110 is initially formed on substrate front side 107 having an opening 111 (cf. FIG. 14). Trench etching may subsequently be carried out, the substrate material being removed in the etching area predefined by opening 111 of mask layer 110 starting from front side 107 until insulating layer 163 of contact structure 161 is reached. Recess 120 produced in this way and present as a blind hole is also provided with an insulating layer 130, as shown in FIG. 15. Insulating layer 130 is formed in recess 120 as well as outside of recess 120 on mask layer 110.

In the context of step 202, an opening 169 is furthermore formed in insulating layers 130, 163 in the bottom area of recess 120, thus exposing contact structure 161, as shown in

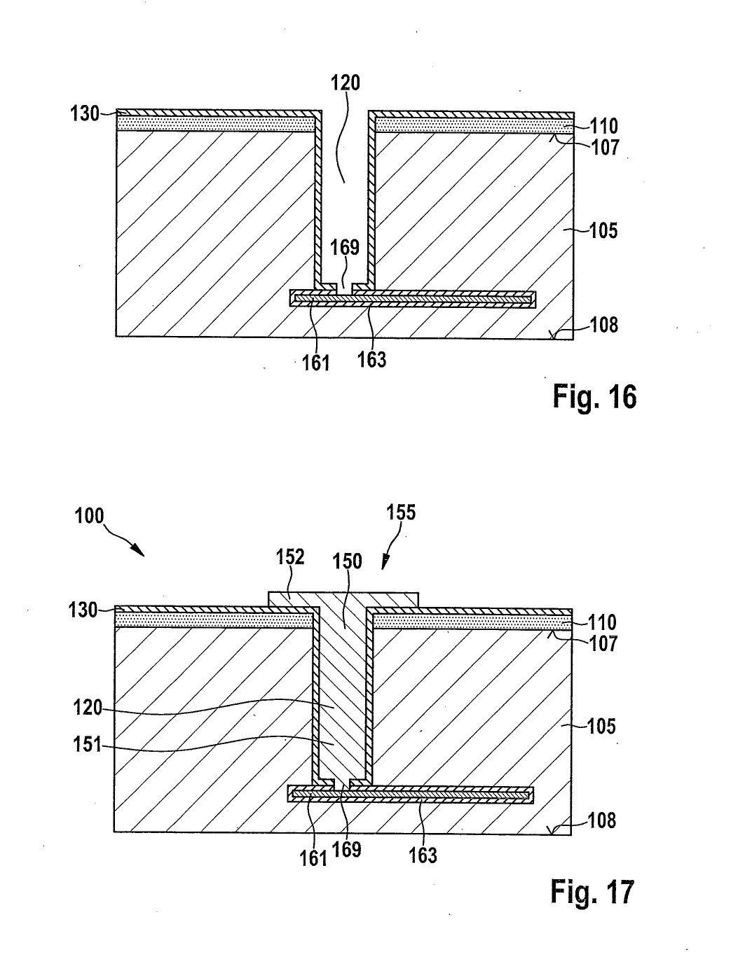

FIG. 16. To achieve this, a suitable etching process may be carried out.

Subsequently, the others of the above-described processes may be carried out, i.e., forming a non-adhesive layer used as wetting protection outside of recess 120 on insulating layer 130 (step 203, not illustrated here), and applying a pourable metallic starting material 150 on substrate 105 (step 204); a wetting may take place in a section 151 within recess 120 and in a front-side section 152 outside of recess 120, as shown in FIG. 17. In the area of opening 169, starting material 150 may be applied directly to contact structure 161, thereby wetting contact structure 161. Pourable starting material 150, which may be applied by “dispensation” or with the aid of a printing process, may, in particular, be an ink or a paste including metallic particles or nanoparticles.

In a subsequent step 205 (cf. FIG. 8), a heating process is carried out, whereby pourable starting material 150 is converted into a solidified metallic through-connection 155. For this purpose, the above-described drying or curing of starting material 150 and sintering of its metal particles may take place. Through-connection 155 produced in this way is connected to buried contact structure 161. Here, too, an outside section 152 of through-connection 155, which may be used as a connecting structure, may be present in the form of a rewiring or printed conductor structure.

To complete component 100 shown in FIG. 17, additional processes combined again in step 206 (cf. FIG. 8) may be carried out. These processes include, for example, removal of the non-adhesive layer, passivating of substrate 105, which has been carried out, if needed, and a separation process.

With the aid of the method described with reference to FIGS. 14 through 17, a plurality of through-connections 155 may also be formed generally simultaneously or in parallel in substrate 105. The method may also be modified in such a way that recess 120 is not manufactured with the aid of a trench etching process, but instead by using a laser, and without using mask layer 110. In this case, subsequently formed insulating layer 130 is also situated outside of recess 120 directly on substrate front side 107 (not illustrated).

The specific embodiments explained with reference to the figures represent preferred or exemplary specific embodiments of the present invention. Instead of the described specific embodiments, other specific embodiments are possible which may include other modifications or combinations of the described features. For example, the above-named materials may be replaced by other materials. Also, it is possible to use other substrates which include a different material or semiconductor material than silicon. Moreover, different processes may be carried out than the ones described and/or additional elements and structures may be formed.

It is also possible to jointly carry out the processes for manufacturing a through-connection 155 and for manufacturing other structures, as described with reference to FIG. 13, in the case of different components as micromechanical components, e.g., in the case of integrated circuits or ASIC chips. It is also possible to manufacture or complete a metallic through-connection 155 only when the component is packaged (ICP, integrated circuit packaging). For example, a component or its substrate 105 provided for packaging may have (only) one recess which is coated with an insulation 130 and which adjoins a contact or printed conductor structure, insulation 130 being open in the area of the contact structure. In this case, a configuration comparable to FIG. 16 may be present. By introducing a pourable starting material 150 and by heating, a through-connection 155 may be produced.

It is furthermore possible to apply a pourable starting material 150 in another way, e.g., over a wide area of a substrate 105, a wetting being “controlled” again with the aid of an appropriately formed non-adhesive layer 140. For example, a centrifugation process with a rotating substrate 105 may be carried out. Another possible method is spray deposition of pourable starting material 150 onto substrate 105.

With regard to the method described with reference to FIGS. 1 through 7, a possible modification is that substrate 105 is completely etched through from front side 107 to back side 108 by trench etching (or alternatively, “laser drilling”), thus producing a through hole 121 which is subsequently provided with an insulating layer 130 and is then metal-coated.

It may also be considered to carry out processes in another sequence, if necessary. For example, the process sequence of FIGS. 3 through 5 may be modified in such a way that non-adhesive layer 140 is formed prior to back thinning of substrate 105.

In addition to that, it is pointed out that, when component 100 or functional substrate 105 shown in FIG. 13 is manufactured, the method described with reference to FIGS. 14 through 17 may (also) be used. In this case, it may be provided that an insulated buried printed conductor structure 161 is formed in the area of substrate side 107 which contacts micromechanical structure 180. A through-connection 155 formed according to FIGS. 14 through 17 may, in this case, extend from substrate side 108 to buried printed conductor structure 161 and may have a connecting structure 152 (instead of contact structure 160 indicated in FIG. 13) present in the area of substrate side 108.

What is claimed is:

1. A method for manufacturing a component having a through-connection, comprising:
providing a semiconductor substrate;
forming a recess in the semiconductor substrate;
introducing into the recess a pourable starting material which has a metal; and
carrying out a heating process, an electrically conductive structure forming the through-connection being developed from the pourable starting material.

2. The method as recited in claim 1, wherein the semiconductor substrate is a silicon substrate.

3. The method as recited in claim 1, wherein the pourable starting material has metal particles.

4. The method as recited in claim 1, wherein the pourable starting material is an ink or a paste.

5. The method as recited in claim 1, wherein the introducing the pourable starting material into the recess is carried out with the aid of a printing process.

6. The method as recited in claim 6, wherein an insulating layer is formed in the recess.

7. The method as recited in claim 1, further comprising:
providing a non-adhesive layer on the semiconductor substrate before the pourable starting material is introduced into the recess.

8. The method as recited in claim 1, wherein the recess into which the pourable starting material is introduced is formed as a through hole in the semiconductor substrate.

9. The method as recited in claim 1, wherein the recess into which the pourable starting material is introduced is formed as a blind hole in the semiconductor substrate and, after carrying out the heating process, a thinning of the semiconductor substrate on one substrate side is carried out to expose the electrically conductive structure on the substrate side.

10. The method as recited in claim 1, further comprising:
forming a contact structure which is connected to the electrically conductive structure.

11. The method as recited in claim 10, wherein the contact structure is a buried contact structure.
